(19) United States
(12) Patent Application Publication
(10) Pub. No.: US 2007/0023850 A1
(43) Pub. Date: Feb. 1, 2007

(54) Bonding surfaces together via plasma treatment on both surfaces with wet treatment on only one surface

(76) Inventors: Chien-Hua Chen, Corvallis, OR (US); Charles C. Haluzak, Corvallis, OR (US); Tracy B. Forrest, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/194,036

(22) Filed: Jul. 30, 2005

(51) Int. Cl. H01L 31/00; H01L 21/46

(52) U.S. Cl. 257/414; 438/455; 257/629; 257/431

(57) ABSTRACT

A first surface is bonded to a second surface. The first surface and the second surface are plasma treated. Only the first surface is wet treated. The first surface and the second surface are joined together to bond the first surface to the second surface.

### BACKGROUND

In semiconductor processing, it is common to have to bond two surfaces together, such as two semiconductor wafer surfaces. Some bonding approaches employ an intermediate layer, such as cement, solder, and so on, applied between the surfaces to bond them together, whereas other bonding approaches do not use any type of adhesive. For the latter bonding approaches, typically the surfaces are treated in some way so that joining them together results in the surfaces being bonded.

In the latter approach, the surfaces are plasma treated, and then both surfaces are wet treated, prior to joining them together. However, some types of surfaces are not amenable to being wet treated. For instance, micro electromechanical system (MEMS) devices can be damaged if subjected to a wet treatment, suffering stiction, contamination problems, as well as possible destruction to fragile components, can occur. More generally, devices containing metals, etched features, or mechanically fragile structures may not be able to be subjected to a wet treatment.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated.

FIG. 1 is a flowchart of a method for bonding a first surface to a second surface, according to an embodiment of the invention.

FIGS. 2A, 2B, 2C, 2D, and 2E are diagrams that illustratively depict the performance of the method of FIG. 1, according to an embodiment of the invention.

FIGS. 3A and 3B are diagrams of an electronic device that may be formed at least in part by performing the bonding process of the method of FIG. 1, according to an embodiment of the invention.

FIG. 4 is a diagram of a projection system that uses the electronic device of FIG. 3A or 3B, according to an embodiment of the invention.

### DETAILED DESCRIPTION OF THE DRAWINGS

In the following detailed description of exemplary embodiments of the invention, reference is made to the accompanying drawings that form a part hereof, and in which is shown by way of illustration, specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

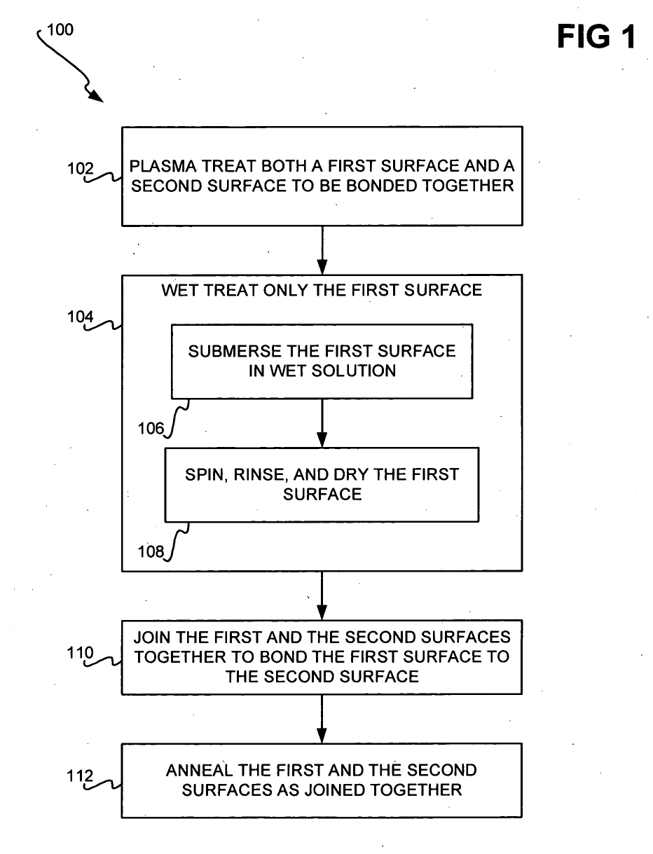

FIG. 1 shows a method 100 for bonding a first surface to a second surface, according to an embodiment of the invention. In general, the method 100 does not employ an adhesive between the first and the second surfaces to bond the surfaces together. Rather, the method 100 treats both the surfaces to increase their surface energies, so that joining the surfaces together results in their being bonded. Prior to performance of the method 100, both the surfaces may be initially cleaned, such as by performing chemical-mechanical polishing (CMP), so that the surfaces have roughness of less than 20 angstroms. The method 100 may, in one embodiment, be employed to at least partially form or fabricate an electronic device having two parts, with corresponding surfaces, that are to be joined together.

First, both the first surface and the second surface are plasma treated (102). Plasma treatment of the surfaces is also referred to as plasma activating the surfaces for later bonding of the surfaces together. The plasma treatment that can be employed may be a high-frequency plasma treatment, using readily available semiconductor processing high-frequency plasma treatment tooling, such as a plasma etcher or reactive ion etcher (RIE) having a 13.56 megahertz (MHz) radio-frequency (RF) power supply. That is, embodiments of the invention do not require special-purpose plasma treatment tools to plasma activate the surfaces to be bonded together. In one embodiment, the plasma treatment used is a nitrogen (N₂) plasma, in which each of the surfaces is treated for forty seconds. The plasma treatment activates the surfaces of various materials, such as silicon (Si), silicon dioxide (SiO₂), silicon nitride (Si₃N₄), gallium arsenide (GaAs), indium phosphide (InP), a glass, a polymer, and so on, by increasing bonding site density and thus their surface energies.

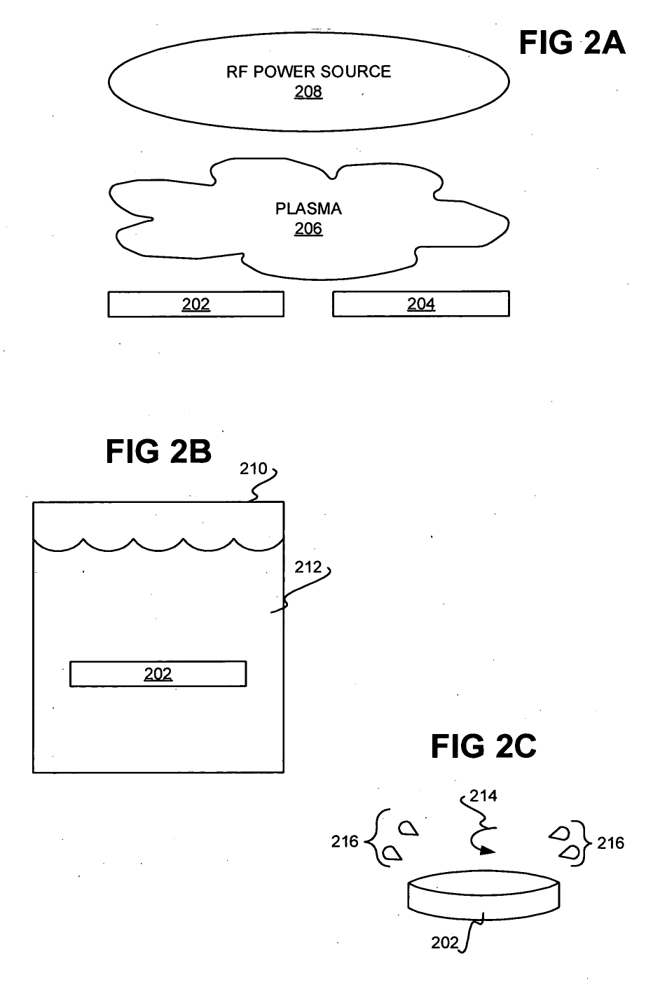

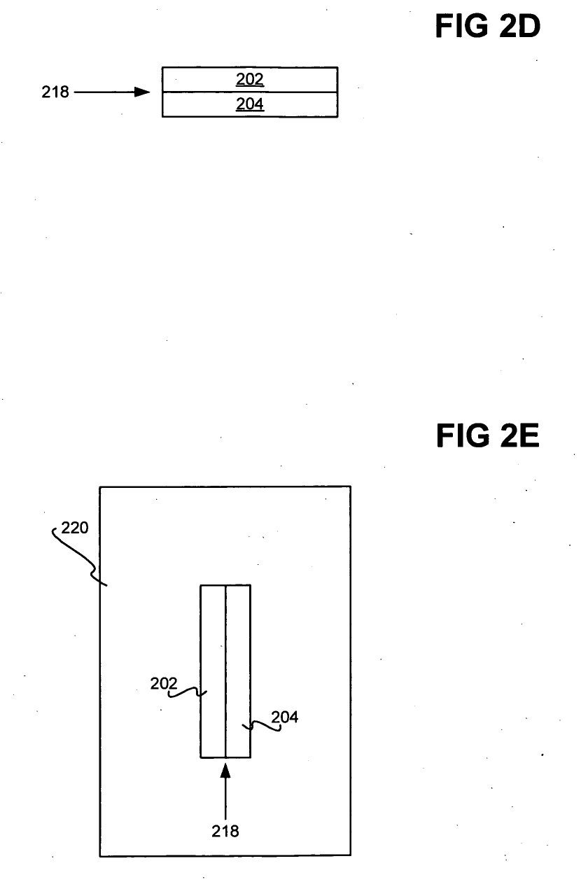

FIG. 2A illustratively depicts the plasma treatment of 102 of the method 100 of FIG. 1 to plasma activate the surfaces to be bonded together, according to an embodiment of the invention. A first surface 202 is to be bonded together to a second surface 204. Both the first and the second surfaces 202 and 204 are subjected to plasma 206, such as nitrogen plasma, in which a radio frequency (RF) power source 208 is turned on to energize the plasma. FIG. 2A specifically depicts the use of a single RF power source. However, more generally, any number of RF power sources may be used, and FIG. 2A is meant to show just one embodiment of the invention, and not limit all embodiments of the invention. As has been described, the surfaces 202 and 204 may be treated for forty seconds. FIG. 2A shows the surfaces 202 and 204 undergoing plasma treatment at the same time. However, the surfaces 202 and 204 may instead undergo plasma treatment at different times.

Referring back to FIG. 1, only the first surface is then wet treated (104). Wet treatment of the first surface hydrates this surface, to attach a mono-layer of water molecules to silicon dangling bonds of the first surface where the first surface is or contains silicon. Hydrating the first surface increases the surface energy of the first surface beyond any increase that may be afforded by the plasma activation of the surface alone. Wet treatment is also referred to as wet dipping, and may be accomplished in one embodiment by performing 106 and 108. Thus, in FIG. 1, only the first surface is submersed in a wet solution (106), and then is spun, rinsed, and dried (108). The wet solution may be what is known within the art as a standard clean 1 (SC1) solution, or the wet solution may be a deionized (DI) water solution. The submersion within the wet solution may be accomplished for thirty seconds in one embodiment.

FIGS. 2B and 2C illustratively depict the wet treatment of 104 of the method 100 of FIG. 1 to hydrate the first surface, according to an embodiment of the invention. FIG. 2B corresponds to the submersion of 106 of the method 100. The first surface 202 is submersed within a wet solution 212 enclosed within a tank 210. FIG. 2C corresponds to the spinning, rinsing, and drying of 108 of the method 100. The first surface 202 is specifically depicted in FIG. 2C as being spun, as indicated by the arrow 214, to drive off wet solution drops 216 from the first surface 202. Thereafter, the first surface 202 is rinsed, and then dried, to further remove the wet solution 212 of FIG. 2B therefrom.

Referring back to FIG. 1, the first and the second surfaces are joined together to initiate the bonding of the surfaces together (110). Because of the high surface energy of the hydrated first surface, the first and the second surfaces can be joined together with minimal force to cause them to bond together. In one embodiment, the first and the second surfaces are pressed together to join them, such as by pressing the edges of the surfaces together. Joining of the first and the second surfaces causes hydrogen bonds to form, resulting in the initial bonding of the surfaces.

FIG. 2D illustratively depicts the joining together of the surfaces in 110 of the method 100 of FIG. 1 to initiate the bonding of the surfaces together, according to an embodiment of the invention. The first surface 202 has been joined to the second surface 204. Joining of the surfaces 202 and 204 results in a bonding interface 218 between the surfaces 202 and 204, at which hydrogen bonds form between the first and the second surfaces 202 and 204.

Referring back to FIG. 1, the first and the second surfaces as joined together are finally annealed (112). Annealing the surfaces as joined together drives off any remaining residual water molecules that resulted from wet treating the first surface, and which was not removed by spinning, rinsing, and drying the first surface. The numerous hydrogen bonds at the bond interface are converted into siloxane bonds. Annealing the surfaces as joined together also finalizes the bonding between them, strengthening this bonding. Because of the high surface energy of the hydrated first surface, the annealing process can be relatively short or accomplished at low temperature, 100 C for ten minutes. Annealing is typically accomplished in an oven.

FIG. 2E illustratively depicts the annealing of 112 of the method 100 of FIG. 1, according to an embodiment of the invention. The first surface 202 and the second surface 204, as joined together and resulting in the bonding interface 218, are placed in an annealing oven 220. The heat of the annealing causes any remaining water molecules resulting from wet treatment of the first surface 202 to be driven off from the bond interface 218.

The method 100 that has been described provides for plasma activation of two surfaces, for bonding the surfaces together, without having to hydrate both surfaces, but rather only having to hydrate one of the surfaces. As such, the method 100 is amenable to bonding semiconductor wafer surfaces together where one of the surfaces could suffer damage if it were subjected to a wet treatment, such as stiction and contamination problems, as well as possible destruction to fragile components. The method 100 is thus amenable to bonding semiconductor wafer surfaces together where one of the surfaces contains metals, etched features, or mechanically fragile structures that may not be able to be subjected to a wet treatment.

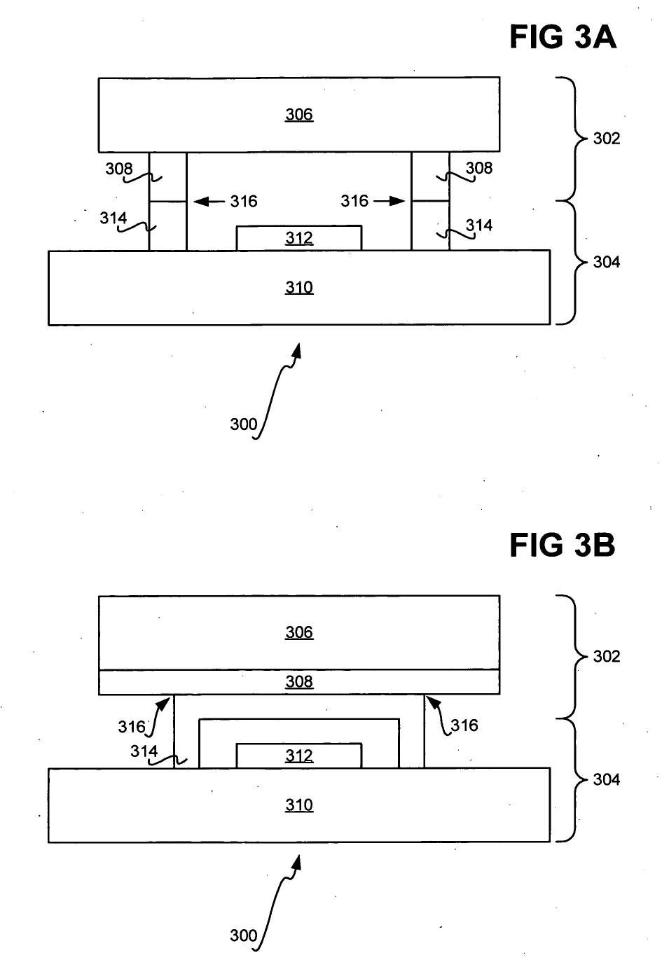

FIGS. 3A and 3B show cross-sectional side profiles of an electronic device 300 that may be formed at least in part by performing the bonding process of the method 100 of FIG. 1, according to varying embodiments of the invention. The electronic device 300 is specifically a light modulator that may be employed in projectors and other types of display devices. The electronic device 300 includes a first part 302 and a second part 304. The second part 304 includes a substrate 310 on which a micro electromechanical systems (MEMS) device 312 has been mounted, and the first part 302 includes an at least substantially transparent thick lid 306 for the MEMS device 312. The lid 306 may be glass in one embodiment of the invention.

The MEMS device 312 of the second part 304 of the electronic device 300 contains sensitive features that may not be able to be subjected to a wet treatment to bond the first part 302 and the second part 304 together. By comparison, the thick lid 306 of the first part 302 does not contain sensitive features, and thus is able to be subjected to hydration to bond the first part 302 and the second part 304 together. Therefore, the first part 302 includes a surface 308 that corresponds to the first surface of the method 100 of FIG. 1 that undergoes a hydration treatment, whereas the second part 304 includes a surface 314 that corresponds to the second surface of the method 100 that does not undergo any such treatment.

The surfaces 308 and 314 may be tetraethoxysilane (TEOS) oxide, silicon, silicon nitride, or another type of surface. In FIG. 3A, the surfaces 308 and 314 are rings, so that light may be transmitted through the lid 306 to and from the MEMS device 312. In FIG. 3B, the surfaces 308 and 314 are layers, and are at least substantially transparent so that light may be transmitted through the lid 306 to and from the MEMS device 312. The surfaces 308 and 314 are bonded together by performing the method 100, such that the parts 302 and 304 that include these surfaces 308 and 314 are likewise bonded together. The surfaces 308 and 314 are bonded together at a bonding interface 316. Thus, no additional substance, such as paste or cement, that provides or promotes adhesion is used to bond the surfaces 308 and 314 together. Such additional substances may be referred to as intermediate layers disposed between the surfaces 308 and 314.

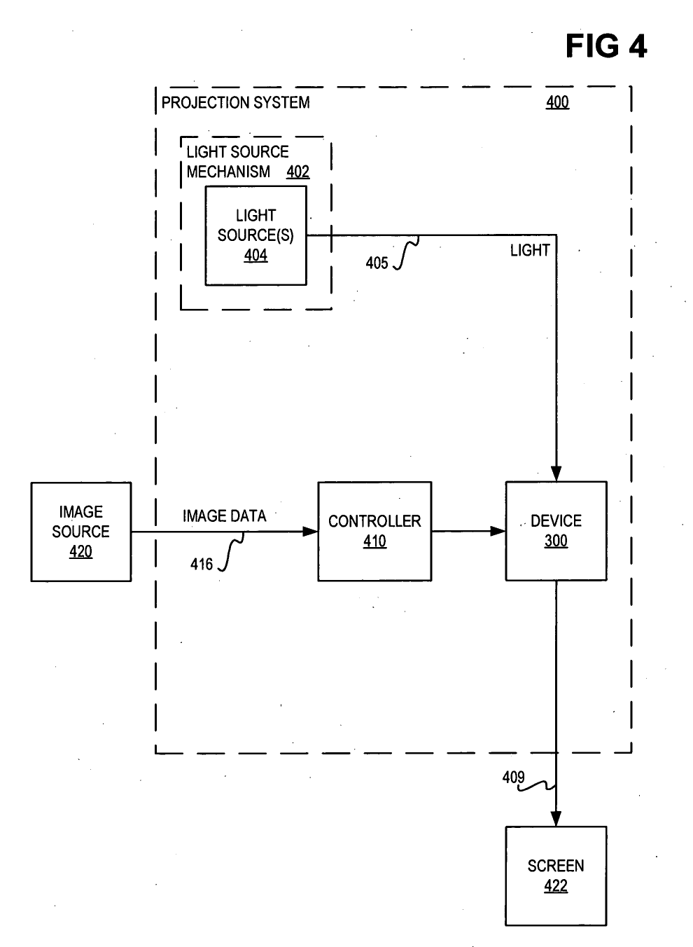

FIG. 4 shows a block diagram of a projection system 400, according to an embodiment of the invention. The system 400 may be implemented as a projector. As can be appreciated by those of ordinary skill within the art, the system 400 includes components specific to a particular embodiment of the invention, but may include other components in addition to or in lieu of the components depicted in FIG. 4. The projection system 400 includes a light source mechanism 402 that includes light source(s) 404, and the electronic device 300 that includes the MEMS device 312. The system 400 also includes a controller 410, and is operatively, or otherwise, coupled to an image source 420 to receive image data 416, as well as a screen 422.

The light source(s) 404 of the light source mechanism 402 output light, such as white light, as indicated by the arrow 405. Each of the light source(s) 404 may be an ultra high pressure (UHP) mercury vapor arc lamp, a xenon arc lamp, or another type of light source. For instance, the light source(s) may be other types of light bulbs, as well as other types of light sources such as light-emitting diodes (LED's), and so on. The light output by the light source(s) 404 is for ultimate modulation by the electronic device 300.

The controller 410 may be implemented in hardware, software, or a combination of hardware and software. The controller 410 receives image data 416 from an image source 420. The image source 420 may be a computing device, such as a computer, or another type of electronic and/or video device. The controller 410 controls the electronic device 300 in accordance with a current frame of the image data 416.

The electronic device 300 thus modulates the light output by the light sources 404 in accordance with the image data 416 as controlled by the controller 410. The image data 416 may be a still image or a moving image, for instance. This light is projected externally or outward from the projection system 400, as indicated by the arrow 409, where it is displayed on the screen 422, or another physical object, such as a wall, and so on. The screen 422 may be a front screen or a rear screen, such that the projection system 400 may be a front-projection system or a rear-projection system, as can be appreciated by those of ordinary skill within the art. The user of the projection system 400, and other individuals able to see the screen 422, are then able to view the image data 416.

It is noted that, although specific embodiments have been illustrated and described herein, it will be appreciated by those of ordinary skill in the art that any arrangement calculated to achieve the same purpose may be substituted for the specific embodiments shown. This application is thus intended to cover any adaptations or variations of the disclosed embodiments of the present invention. Therefore, it is manifestly intended that this invention be limited only by the claims and equivalents thereof.

We claim:

1. A method for bonding a first surface to a second surface comprising:
plasma treating the first surface and the second surface;
wet treating only the first surface; and,
joining the first surface and the second surface together to bond the first surface to the second surface.

2. The method of claim 1, wherein the first surface is bonded to the second surface without employing an intermediate layer between the first surface and the second surface.

3. The method of claim 1, further comprising annealing the first surface and the second surface as joined together.

4. The method of claim 3, wherein annealing the first surface and the second surface as joined together drives off water molecules resulting from wet treating the first surface and strengthens bonding of the first surface to the second surface.

5. The method of claim 1, wherein plasma treating the first surface and the second surface comprises employing a plasma treatment tool.

6. The method of claim 1, wherein plasma treating the first surface and the second surface activates the first surface and the second surface for subsequent bonding of the first surface to the second surface.

7. The method of claim 1, wherein wet treating only the first surface comprises:
hydrating the first surface in a wet solution; and,
spinning, rinsing, and drying the first surface.

8. The method of claim 7, wherein hydrating the first surface within the wet solution comprises submersing the first surface within a standard clean 1 (SC1) solution or a deionized (DI) water solution.

9. The method of claim 1, wherein wet treating only the first surface comprises hydrating the first surface to attach a mono-layer of water molecules to silicon dangling bonds of the first surface.

10. The method of claim 1, wherein joining the first surface and the second surface together comprises pressing the first surface to the second surface with minimal force.

11. The method of claim 1, wherein joining the first surface and the second surface together forms hydrogen bonds between the first surface and the second surface.

12. An electronic device formed at least in part by a method to bond a first surface of a first part of the electronic device with a second surface of a second part of the electronic device, comprising:
plasma activating the first and the second surfaces to increase silicon dangling bond density of the first and the second surfaces;
hydrating only the first surface to attach a mono-layer of water molecules to silicon dangling bonds of the first surface; and,
joining the first and the second surfaces together to form bonds between the first and the second surfaces.

13. The electronic device of claim 12, wherein the first surface is bonded to the second surface without employing an intermediate layer between the first and the second surfaces.

14. The electronic device of claim 12, wherein the method further comprises annealing the electronic device to strengthen bonding of the first and the second surfaces.

15. The electronic device of claim 12, wherein plasma activating the first and the second surfaces comprises plasma treating the first and the second surfaces.

16. The electronic device of claim 12, wherein hydrating only the first surface comprises submersing the first part of the electronic device within a standard clean 1 (SC1) solution or a deionized (DI) water solution.

17. The electronic device of claim 12, wherein hydrating the first surface increases surface energy of the first surface.

18. The electronic device of claim 12, wherein joining the first and the second surfaces together comprises pressing the first surface to the second surface with minimal force.

19. The electronic device of claim 12, wherein the first part of the electronic device comprises a micro electromechanical systems (MEMS) device lid, and the second part of the electronic device comprises a MEMS device.

20. The electronic device of claim 12, wherein each of the first and the second surfaces comprises one of: a tetraethoxysilane (TEOS) oxide surface, a silicon surface, a silicon nitride surface, a glass surface, a polymer surface, a silicon dioxide surface, a gallium arsenide surface, and an indium phosphide surface.

21. An electronic device comprising:
a first part having a first surface;
a second part having a second surface; and,
a bonding interface between the first and the second surfaces, the bonding interface resulting from plasma treatment of the first and the second surfaces and from wet treatment of only the first surface.

22. The electronic device of claim 21, wherein the first part of the electronic device comprises a micro electromechanical systems (MEMS) device lid, and the second part of the electronic device comprises a MEMS device.

23. The electronic device of claim 21, wherein each of the first and the second surfaces comprises a ring.

24. The electronic device of claim 21, wherein each of the first and the second surfaces comprises one of: a tetraethoxysilane (TEOS) oxide surface, a silicon surface, a silicon nitride surface, a glass surface, a polymer surface, a silicon dioxide surface, a gallium arsenide surface, and an indium phosphide surface.

25. The electronic device of claim 21, wherein the bonding interface further results from joining the first and the second surfaces together and annealing the first and the second surfaces.

26. The electronic device of claim 21, wherein the bonding interface comprises hydrogen bonds between the first and the second surfaces, the plasma treatment of the first and the second surfaces increasing silicon dangling bond density of the first and the second surfaces, and the wet treatment of the first surface attaching a mono-layer of water molecules to silicon dangling bonds of the first surface.

27. An electronic device comprising:
a first part having a first surface;
a second part having a second surface; and,
means for bonding the first and the second surfaces resulting from plasma treating the first and the second surfaces and wet treating only the first surface.

28. A projection system comprising:
an electronic device to modulate light, the electronic device having two parts bonded together resulting from plasma treatment of both of the parts and from wet treatment of only one of the parts; and,
a controller to control the electronic device in accordance with image data so that the electronic device is to modulate the light in accordance with the image data.

29. The projection system of claim 28, wherein a first part of the electronic device comprises a micro electromechanical systems (MEMS) device lid, and a second part of the electronic device comprises a MEMS device.

30. The projection system of claim 28, wherein the two parts of the electronic device are bonded together as further resulting from joining the two parts together and annealing the two parts.
